(19) United States
(12) Patent Application Publication
(10) Pub. No.: US 2024/0042487 A1
(43) Pub. Date: Feb. 8, 2024

(54) VIBRATION DEVICE, VIBRATION APPARATUS, AND MANUFACTURING METHOD OF VIBRATION DEVICE

(71) Applicant: OMRON Corporation, KYOTO (JP)

(72) Inventors: Shogo NAGASAKA, KYOTO (JP); Yoshinori SHIMIZU, KYOTO (JP)

(73) Assignee: OMRON Corporation, KYOTO (JP)

(21) Appl. No.: 18/346,789

(22) Filed: Jul. 4, 2023

(30) Foreign Application Priority Data
Aug. 3, 2022 (JP) 2022-123740

(51) Int. Cl. B06B 1/06

(52) U.S. Cl. CPC B06B 1/0648; B06B 1/0688

(57) ABSTRACT

Provided are a vibration device, a vibration apparatus, and a method for manufacturing a vibration device. The vibration device includes a vibration element; a substrate having a placement surface on which the vibration element is placed; a wall portion formed around the placement surface; and a potting layer for sealing the vibration element placed on the placement surface of the substrate inside the wall portion. The vibration device is manufactured by forming the substrate by laminating a protective film having an opening on a base film; placing the vibration element in the opening of the protective film on the substrate; and sealing the vibration element placed in the opening of the protective film on the substrate by potting.

### RELATED APPLICATION CROSS-REFERENCE

This application claims the priority benefits of Japanese application no. 2022-123740, filed on Aug. 3, 2022. The entirety of the above-mentioned patent application is hereby incorporated by reference herein and made a part of this specification.

### BACKGROUND

### Technical Field

The disclosure relates to a vibration device including a vibration element, a vibration apparatus including such a vibration device, and a manufacturing method of a vibration device for manufacturing such a vibration device.

### Related Art

Vibration elements that generate vibrations are used in various electronic devices, such as operation devices like mice, keyboards, and game controllers, and communication devices like smartphones and tablet computers, and the like. For example, Patent Literature 1 discloses a vibration device using a piezoelectric element as a vibration element. In the vibration device using a piezoelectric element, it is easy for the piezoelectric element to fail due to vibrations, so lamination processing with PET (Polyethylene Terephthalate) film is required.

### CITATION LIST

### Patent Literature

[Patent Literature 1] Japanese Unexamined Patent Application Publication No. 2022-39770

### SUMMARY

### Technical Problem

However, the lamination processing using PET has a problem that the vibration caused by the vibration element is easily attenuated.

The disclosure provides a vibration device capable of suppressing attenuation of vibrations.

The disclosure provides a vibration apparatus including a vibration device according to the disclosure.

Furthermore, the disclosure provides a manufacturing method of the vibration device.

### Solution to Problem

A vibration device disclosed in this application includes a vibration element; a substrate having a placement surface on which the vibration element is placed; a wall portion formed around the placement surface; and a potting layer for sealing the vibration element placed on the placement surface of the substrate inside the wall portion surround by the wall portion.

Furthermore, a vibration apparatus disclosed in this application includes the vibration device.

Furthermore, a manufacturing method of the vibration device disclosed in this application includes forming a substrate by laminating a protective film having an opening on a base film; placing the vibration element in the opening of the protective film on the substrate; and sealing the vibration element placed in the opening of the protective film on the substrate by potting.

### Effects

The vibration device and the like disclosed in this application have excellent effects, such as the ability to suppress the attenuation of vibrations.

### BRIEF DESCRIPTION OF THE DRAWINGS

FIG. 1 is a schematic external view showing an example of the appearance of a vibration apparatus disclosed in this application.

FIG. 2 is a schematic external view showing an example of the appearance of a vibration apparatus disclosed in this application.

FIG. 3 is a schematic perspective view showing an example of the inside of a vibration apparatus disclosed in this application.

FIG. 4 is a schematic perspective view showing an example of a vibration device disclosed in this application.

FIG. 5 is a schematic perspective view showing an example of a substrate provided in the vibration device disclosed in this application.

FIG. 6 is a schematic exploded perspective view showing an example of a substrate provided in the vibration device disclosed in this application.

FIG. 7 is a schematic exploded perspective view showing an example of a vibration device disclosed in this application.

FIG. 8 is a schematic sectional view schematically showing an example of a vibration device disclosed in this application.

FIG. 9 is an explanatory diagram showing an example of a manufacturing method of the vibration device disclosed in this application.

FIG. 10 is an explanatory diagram showing an example of a manufacturing method of the vibration device disclosed in this application.

FIG. 11 is an explanatory diagram showing an example of a manufacturing method of the vibration device disclosed in this application.

FIG. 12 is an explanatory diagram showing an example of a manufacturing method of the vibration device disclosed in this application.

FIG. 13 is an explanatory diagram showing an example of a manufacturing method of the vibration device disclosed in this application.

FIG. 14 is a graph showing an example of the vibration characteristics of the vibration device disclosed in this application.

### DESCRIPTION OF THE EMBODIMENTS

In the vibration device, the substrate includes a base film on which the placement surface is formed; and a protective film laminated on the base film and having an opening corresponding to the placement surface. The wall portion is formed by a step between the placement surface of the base film and the protective film.

In the vibration device, the potting layer is formed so as not to protrude from the inside of the wall portion.

In the vibration device, the potting layer has a height from the placement surface equal to or less than the wall portion.

In the vibration device, the vibration element is a thin-film piezoelectric element that vibrates when energized, and the substrate is a thin-film flexible printed circuit board.

### Application Example

Hereinafter, embodiments will be described with reference to the drawings. The vibration apparatus disclosed in this application is applicable to devices that convey situations or information to users through vibrations, such as devices with integrated operation parts and display parts like game devices and game device controllers. Hereinafter, a vibration apparatus VA applied to a game device will be described as an example with reference to the drawings.

<Appearance of Vibration Apparatus VA>

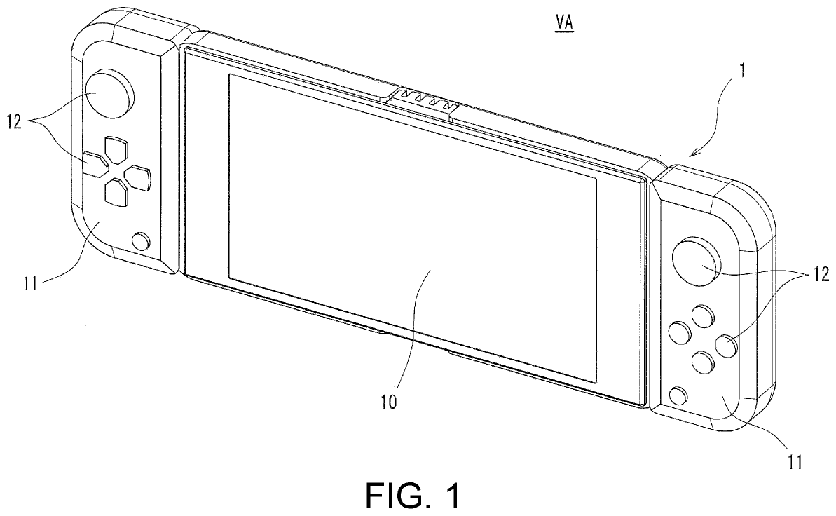

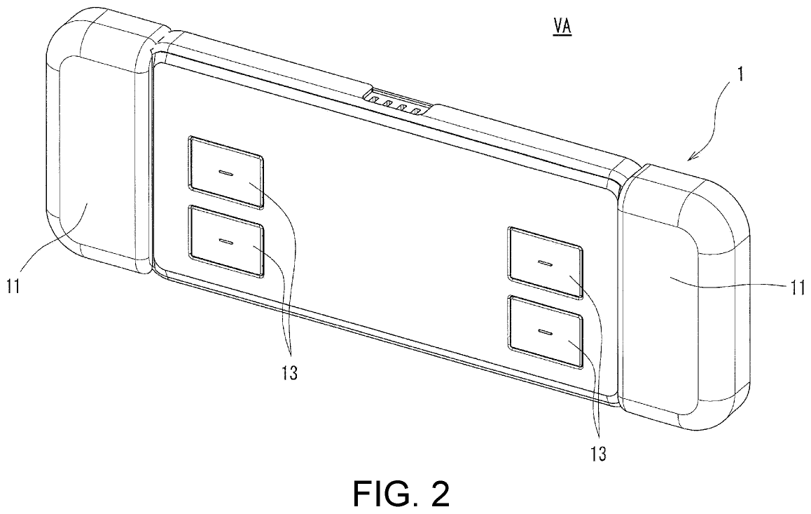

FIGS. 1 and 2 are schematic appearance diagrams showing an example of the appearance of the vibration apparatus VA disclosed in this application. FIG. 1 is a schematic perspective view showing the front side of the vibration apparatus VA, and FIG. 2 is a schematic perspective view showing the back side of the vibration apparatus VA. The vibration apparatus VA includes a housing 1 having a substantially rectangular plate shape, and a display unit 10 such as a rectangular liquid crystal panel is arranged at the center of the front surface of the housing 1, with holding portions 11 for users to grip arranged on both sides of the display unit 10. Operation units 12, such as operation buttons for users to operate with their thumbs, are arranged on the holding portions 11. On the back surface of the housing 1, vibration units 13 that generate vibrations are arranged at four positions where fingers other than the user's thumb may touch.

<Internal Structure of Vibration Apparatus VA>

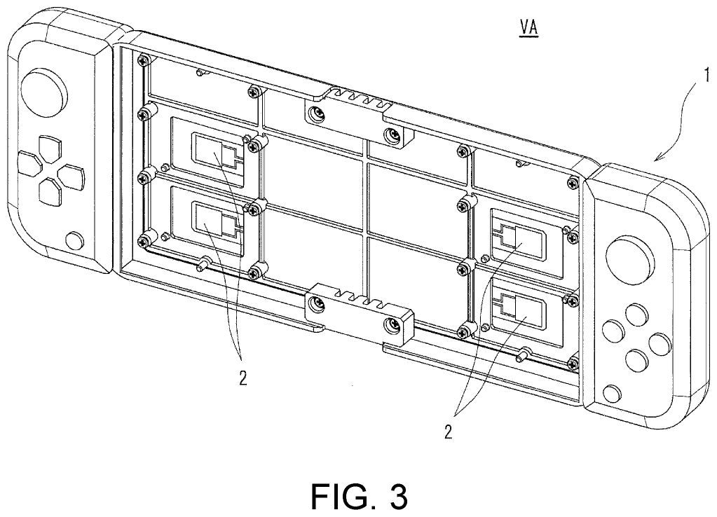

FIG. 3 is a schematic perspective view showing an example of the inside of the vibration apparatus VA disclosed in this application. In FIG. 3, the display unit 10 arranged on the front surface of the housing 1 of the vibration apparatus VA is removed such that the internal structure is visible. To make it easier to see the inside of the vibration apparatus VA, FIG. 3 shows only the housing 1 and vibration devices 2 arranged inside the housing 1. As illustrated in FIG. 3, four vibration devices 2 are arranged inside the housing 1, and the arrangement positions of each vibration device 2 correspond to the positions of the vibration units 13 on the back surface of the housing 1. With such an arrangement, vibrations from the vibration devices 2 are transmitted to the user's fingertips through the vibration units 13 of the housing 1.

<Structure of Vibration Device 2>

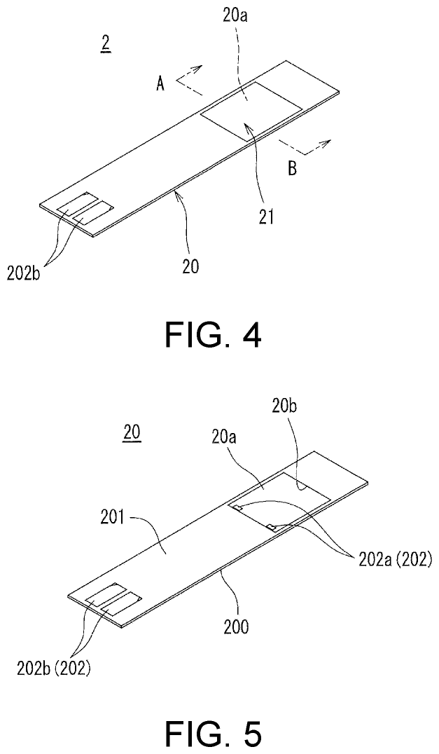

FIG. 4 is a schematic perspective view showing an example of the vibration device 2 disclosed in this application. The vibration device 2 includes a vibration element 21, a substrate having a substantially rectangular thin film shape, and a terminal portion 202b connected to a control unit (not shown) for controlling the vibration element 21. The vibration element 21 is placed on a placement surface 20a of the substrate 20. The substrate 20 is a flexible printed circuit board (FPC board) having flexibility.

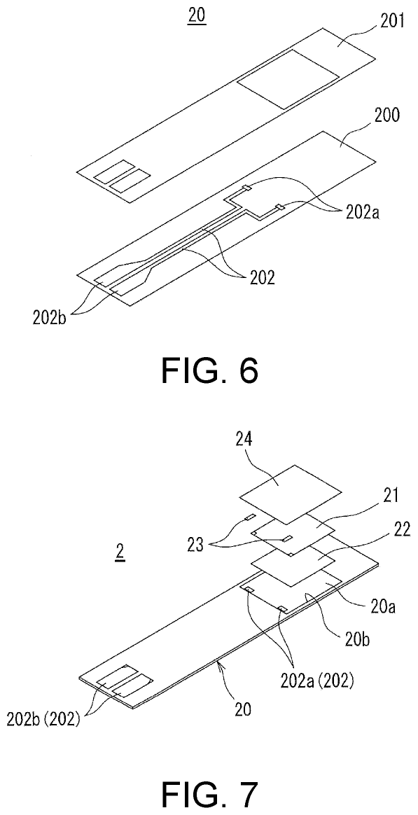

FIG. 5 is a schematic perspective view showing an example of the substrate 20 provided in the vibration device 2 disclosed in this application. FIG. 6 is a schematic exploded perspective view showing an example of the substrate 20 provided in the vibration device 2 disclosed in this application. The substrate 20 provided in the vibration device 2 is formed by laminating a thin film-shaped protective film 201 on a thin film-shaped base film 200. The thickness of the base film 200 is about 50 μm. A part of the surface of the base film 200 forms the substantially square placement surface 20a. A pair of printed wirings 202 are formed on the base film 200. One end of the printed wirings 202 serves as an electrode portion 202a connected to the vibration element 21, and the other end serves as the terminal portion 202b. The protective film 201 is a thin film with a thickness of about 50 μm made of resin such as PET (Polyethylene Terephthalate), and it covers the surface of the base film 200. The protective film 201 has openings corresponding to the placement surface 20a and the terminal portion 202b of the printed wirings 202. The opening corresponding to the placement surface 20a forms a step of 50 μm between the upper surface of the base film 200 and the upper surface of the protective film 201, and due to this step, the opening edge of the protective film 201 becomes a wall portion 20b.

FIG. 7 is a schematic exploded perspective view showing an example of the vibration device 2 disclosed in this application. FIG. 7 shows various members stacked on the placement surface 20a of the substrate 20 provided in the vibration device 2 in a disassembled manner. The placement surface 20a in the base film 200 of the substrate 20 is a substantially square-shaped area within the opening of the stacked protective film 201. The placement surface 20a has an adhesive layer 22, the vibration element 21, a conductive paste 23, and a potting layer 24 stacked thereon. The adhesive layer 22 is a layer that adheres the vibration element 21 to the base film 200 and is formed by an adhesive. The vibration element 21 is formed using, for example, a piezoelectric element having piezoelectricity such as PZT (lead zirconate titanate), and vibrates when energized. The conductive paste 23 is formed by a conductive adhesive such as silver paste, which electrically connects the vibration element 21 and the electrode portion 202a of the printed wirings 202. The potting layer 24 is formed by a sealing agent made of cured resin.

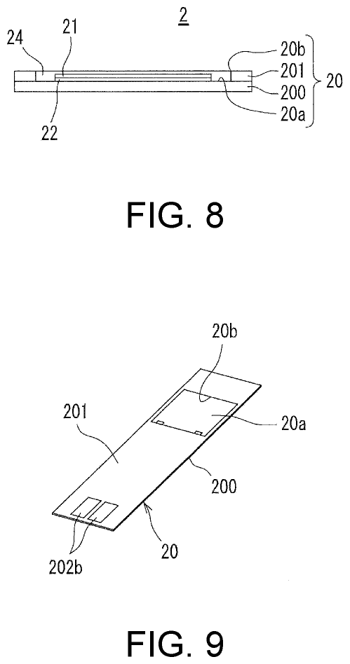

FIG. 8 is a schematic cross-sectional view showing an example of the vibration device 2 disclosed in this application. FIG. 8 schematically shows a cross-section of the vibration device 2 cut along line A-B in FIG. 4 and passing through the placement surface 20a. The substrate 20 has the placement surface 20a and the wall portion 20b formed by laminating the protective film 201 having openings on the base film 200. The film thicknesses of the base film 200 and the protective film 201 are both 50 μm. Thus, the area surrounded by the wall portion 20b on the placement surface 20a forms a recess having a height of 50 μm, which serves as a dam to prevent the outflow of potting resin. The adhesive layer 22, the vibration element 21, and the potting layer 24 are laminated on the placement surface 20a. The potting layer 24 for sealing members such as the vibration element 21 is filled such that its height from the placement surface is equal to or less than 50 μm. That is, the potting layer 24 is formed such that its height from the placement surface 20a is equal to or less than the height of the wall portion 20b and does not protrude from inside the wall portion 20b. It should be noted that the height of the potting layer 24 may be filled to slightly exceed the height of the wall portion 20b if it is within a range that allows attenuation of vibrations; however, it is preferable to ensure that it does not protrude out from inside the wall portion 20b.

<Manufacturing Method of Vibration Device 2>

Next, the manufacturing method of the vibration device 2 according to this disclosure will be described. FIGS. 9 to 13 are explanatory diagrams showing an example of the manufacturing method of the vibration device 2 according to this disclosure. FIG. 9 shows a process of forming the substrate 20 by attaching the printed wirings 202 to the base film 200 and laminating the protective film 201 thereon. By adhering the protective film 201 having openings formed to the base film 200, the placement surface 20a and the wall portion 20b are formed. Moreover, by adhering the protective film 201 to the base film 200, most of the printed wirings 202 is covered, and the electrode portion 202a and the terminal portion 202b are exposed from the openings of the protective film 201.

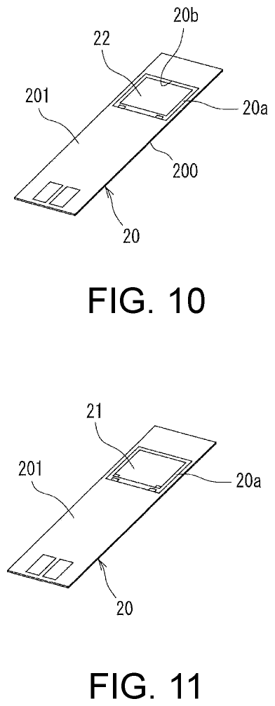

FIG. 10 shows a process of forming the adhesive layer 22 on the placement surface surrounded by the wall portion 20b from the state shown in FIG. 9. The adhesive layer 22 is formed as a layer with a thickness of 10 to 30 μm by applying a liquid adhesive or laying a sheet-like adhesive on the placement surface 20a. By using a liquid adhesive or a thin-film adhesive sheet, it is possible to form the adhesive layer 22 with a substantially uniform film thickness. Since the adhesive layer 22 is a layer for adhering the vibration element 21 to the base film 200, it is preferable that the application range is equivalent to the surface on the adhesive side of the vibration element 21.

FIG. 11 shows a process of placing the vibration element 21 on the adhesive layer 22 formed on the placement surface 20a within the opening of the protective film 201 from the state shown in FIG. 10. By placing the vibration element 21 on the adhesive layer 22 formed on the placement surface 20a of the base film 200 of the substrate 20 and making it adhere, the vibration element 21 is temporarily adhered. The substrate 20 with the temporarily adhered vibration element 21 is heated in a heat-curing furnace, causing the adhesive layer 22 to cure and adhere the vibration element 21 to the substrate 20.

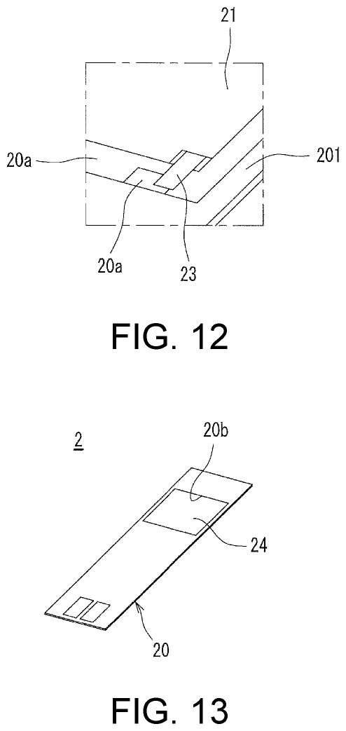

FIG. 12 shows a process of forming the conductive paste 23 from the state shown in FIG. 11. FIG. 12 shows an enlarged view of the area around the conductive paste 23. The layer of the conductive paste 23 is formed by applying silver paste to connect the electrode portion 202a of the printed wirings 202 formed on the substrate 20 and the electrode of the vibration element 21 (not shown), and then curing it using a curing method such as heat curing or UV curing.

FIG. 13 shows a process of sealing the vibration element 21 placed within the opening on the substrate 20 with a potting agent from the state shown in FIG. 12. The potting agent is poured into the opening on the substrate 20 where members such as the vibration element 21 are placed, that is, into the recess surrounded by the wall portion 20b, and cured using a curing method such as heat curing or UV curing. In this way, the potting layer 24 is formed. The amount of potting agent poured is adjusted so as not to exceed the height of the wall portion 20b. In this manner, the vibration device 2 is manufactured.

<Vibration Characteristics of Vibration Device 2>

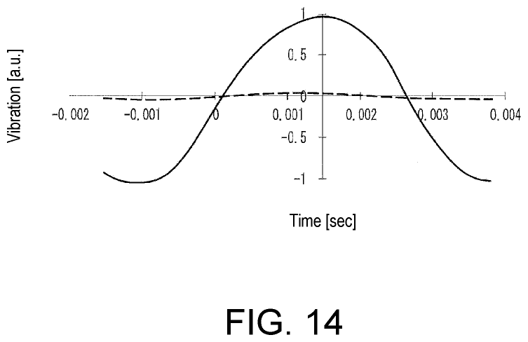

FIG. 14 is a graph showing an example of the vibration characteristics of the vibration device 2 disclosed in this application. FIG. 14 is a graph showing the relationship between time on the horizontal axis and vibration on the vertical axis. The solid line represents the vibration device 2 disclosed in this application, and the dashed line represents a conventional vibration device in which the vibration element is sealed with a PET laminate for comparison. The substrate and vibration element are under the same conditions. The conventional PET laminate-based vibration device is manufactured using a general manufacturing method, in which a PET laminate layer is formed on a 50 μm substrate and has a total film thickness of 120 μm. In the potting-based vibration device 2 disclosed in this application, since the potting agent is poured into the recess, it is possible to make the potting layer 24 thinner, and the 50 μm potting layer 24 is formed on the substrate 20, resulting in a total film thickness of 100 μm. The driving conditions for both are set to a sinusoidal waveform with a voltage of 30V and a frequency of 200 Hz. Vibration is detected by irradiating laser light from a laser Doppler vibrometer onto the surface of the vibration element. The vibration device 2 disclosed in this application, which seals the vibration element 21 with the thin potting layer 24, exhibits less attenuation of vibration and larger observed vibrations compared to conventional devices.

As described above, in the vibration element 21 disclosed in this application, a potting agent is poured into the recess formed by the wall portion 20b to form the potting layer 24 having a height equal to or less than the wall portion 20b. As a result, by protecting the vibration element 21 with the potting layer 24, the vibration element 21 disclosed in this application can be improved in durability, and can suppress attenuation of vibration, among other excellent effects, to enhance high vibration performance.

Furthermore, since the vibration element 21 disclosed in this application forms the wall portion 20b at a step formed by laminating the protective film 201 having openings on the base film 200, it exhibit excellent effects such as being manufactured without complicating the process.

The disclosure is not limited to the embodiments described above and may be implemented in various other forms. Thus, the described embodiments are merely illustrative in all respects and should not be construed as limiting. The technical scope of the disclosure is defined by the claims and is not bound by the text of the specification. Furthermore, modifications and changes that belong to the equivalent scope of the claims are all within the scope of the disclosure.

For example, in the aforementioned embodiment, the wall portion 20b is formed by laminating the protective film 201 having openings on the base film 200 has been shown, but the vibration device 2 disclosed in this application is not limited thereto and may be implemented in various forms. For instance, the vibration device 2 disclosed in this application may be implemented in various forms, such as forming the wall portion 20b by providing a protrusion on the substrate 20, as long as it is possible to pour the potting agent.

Moreover, for example, in the aforementioned embodiment, the application of the vibration apparatus VA disclosed in this application to a game device controller has been described, but the vibration apparatus VA disclosed in this application is not limited thereto and may be applied to various devices that convey situations or information to users through vibrations.

What is claimed is:

1. A vibration device, comprising:
a vibration element;
a substrate having a placement surface on which the vibration element is placed;
a wall portion formed around the placement surface; and
a potting layer for sealing the vibration element placed on the placement surface of the substrate inside the wall portion surrounded by the wall portion.

2. The vibration device according to claim 1,
wherein the substrate comprises:
a base film on which the placement surface is formed; and
a protective film laminated on the base film and having an opening corresponding to the placement surface,
wherein the wall portion is formed by a step between by the placement surface of the base film and the protective film.

3. The vibration device according to claim 1,
wherein the potting layer is formed so as not to protrude from the inside of the wall portion.

4. The vibration device according to claim 2,
wherein the potting layer is formed so as not to protrude from the inside of the wall portion.

5. The vibration device according to claim 1,
wherein the potting layer has a height from the placement surface equal to or less than the wall portion.

6. The vibration device according to claim 2,
wherein the potting layer has a height from the placement surface equal to or less than the wall portion.

7. The vibration device according to claim 1,
wherein the vibration element is a thin-film piezoelectric element that vibrates when energized, and
the substrate is a thin-film flexible printed circuit board.

8. The vibration device according to claim 2,
wherein the vibration element is a thin-film piezoelectric element that vibrates when energized, and
the substrate is a thin-film flexible printed circuit board.

9. A vibration apparatus, comprising a vibration device according to claim 1.

10. A vibration apparatus, comprising a vibration device according to claim 2.

11. A method for manufacturing a vibration device provided with a vibration element, the method comprising:
forming a substrate by laminating a protective film having an opening on a base film;
placing the vibration element in the opening of the protective film on the substrate; and
sealing the vibration element placed in the opening of the protective film on the substrate by potting.
